(19) United States
(12) Patent Application Publication
(10) Pub. No.: US 2022/0384585 A1
(43) Pub. Date: Dec. 1, 2022

(54) INTEGRATED ELECTRONIC CIRCUIT INCLUDING A FIELD PLATE FOR THE LOCAL REDUCTION OF THE ELECTRIC FIELD AND RELATED MANUFACTURING PROCESS

(71) Applicant: STMicroelectronics S.r.l., Agrate Brianza (MB) (IT)

(72) Inventors: Elisabetta PIZZI, Limbiate (IT); Dario RIPAMONTI, Monza (IT); Matteo PATELMO, Trezzo Sull'Adda (IT); Fabrizio Fausto Renzo TOIA, Busto Arsizio (VA) (IT); Simone Dario MARIANI, Vedano al Lambro (MB) (IT)

(73) Assignee: STMicroelectronics S.r.l., Agrate Brianza (MB) (IT)

(21) Appl. No.: 17/824,566

(22) Filed: May 25, 2022

(30) Foreign Application Priority Data
May 31, 2021 (IT) 102021000014180

(51) Int. Cl. H01L 29/40; H01L 29/06; H01L 29/43; H01L 49/02

(52) U.S. Cl. CPC H01L 29/402; H01L 29/401; H01L 29/0607; H01L 29/43; H01L 28/75

(57) ABSTRACT

An integrated electronic circuit including: a dielectric body delimited by a front surface; A top conductive region of an integrated electronic circuit extend within a dielectric body having a front surface. A passivation structure including a bottom portion and a top portion laterally delimits an opening. The bottom portion extends on the front surface, and the top portion extends on the bottom portion. A field plate includes an internal portion and an external portion. The internal portion is located within the opening and extends on the top portion of the passivation structure. The external portion extends laterally with respect to the top portion of the passivation structure and contacts at a bottom one of: the dielectric body or the bottom portion of the passivation structure. The opening and the external portion are arranged on opposite sides of the top portion of the passivation structure.

### PRIORITY CLAIM

This application claims the priority benefit of Italian Application for Patent No. 102021000014180, filed on May 31, 2021, the content of which is hereby incorporated by reference in its entirety to the maximum extent allowable by law.

### TECHNICAL FIELD

Embodiments herein concern an integrated electronic circuit including a field plate, which enables local reduction of the electric field and furthermore a related manufacturing process.

### BACKGROUND

As is known, today numerous types of integrated electronic circuits are available, which include layers of dielectric material that must be appropriately sized in order to withstand the electric fields that, in use, develop within the integrated electronic circuits, without there arising the so-called phenomenon of uncontrolled breakdown of the dielectric material.

For instance, integrated electronic circuits are known that each include a corresponding high-voltage passive electronic component, such as a capacitor, which in turn includes a pair of conductive plates, between which dielectric material is interposed. In this case, the integrated electronic circuit is designed so that, when it is subjected to voltages that fall within an operating range envisaged, breakdown of the dielectric material interposed between the plates does not occur. However, the electric field may reach critical values not only within the dielectric material interposed between the plates (also known as active dielectric layer), but also in other portions of dielectric material that form the integrated electronic circuit. In particular, it is known how integrated electronic circuits include contact structures, which enable ohmic connection of the integrated electronic circuits to the outside world. Such contact structures include conductive parts, also known as pads, and passivation regions, the latter being subjected to high electric fields that are generated in the proximity of the edges of the pads and thus being at risk of uncontrolled dielectric breakdown.

In this connection, it has been proposed to make the pads of nickel and palladium, which are grown electrochemically and enable formation of pads having chamfered profiles, with consequent reduction of the local electric field, with respect to what would be found in the presence of pads with sharper edges. However, the adoption of such materials is not always possible, for example on account of the technological constraints imposed by the manufacturing process or of constraints of cost. Furthermore, the need to reduce the electric fields is felt not only as regards the contact pads and the surrounding dielectric regions, but rather more in general. In this connection, it is known that the integrated electronic circuits are provided with various metallization levels.

There is a need in the art to control and, where possible, reduce the electric fields that develop in the dielectric regions that overlie the higher metallization level, i.e., the front metallization level.

There is a need in the art for an integrated electronic circuit that will meet at least in part the aforementioned needs.

### SUMMARY

Embodiments concern an integrated electronic circuit and a manufacturing process.

In an embodiment, an integrated electronic circuit comprises: a dielectric body delimited by a respective front surface; a top conductive region, which extends within the dielectric body, starting from the front surface of the dielectric body; and a first passivation structure including a bottom portion, which extends on the front surface, and a top portion, which extends on the bottom portion, said first passivation structure laterally delimiting at least part of an opening, the top conductive region giving out onto said opening.

The integrated electronic circuit further comprises a field plate of conductive material, which includes: an internal portion, which extends within the opening, in contact with the top conductive region, and on the top portion of the first passivation structure; and an external portion, which extends laterally with respect to the top portion of the first passivation structure and contacts at the bottom the dielectric body or the bottom portion of the first passivation structure, said opening and said external portion being arranged on opposite sides of the top portion of the first passivation structure.

In an embodiment, a process for manufacturing an integrated electronic circuit comprises: forming a dielectric body delimited by a respective front surface; forming a top conductive region, which extends within the dielectric body, starting from the front surface of the dielectric body; forming a first passivation structure including a bottom portion, which extends on the front surface, and a top portion, which extends on the bottom portion, said first passivation structure laterally delimiting at least part of an opening, the top conductive region giving out onto said opening; and forming a field plate of conductive material.

The step for forming the field plate includes: forming an internal portion, which extends within the opening, in contact with the top conductive region, and on the top portion of the first passivation structure; and forming an external portion, which extends laterally with respect to the top portion of the first passivation structure and contacts at the bottom the dielectric body or the bottom portion of the first passivation structure, said opening and said external portion being arranged on opposite sides of the top portion of the first passivation structure.

### BRIEF DESCRIPTION OF THE DRAWINGS

For a better understanding of the present invention, preferred embodiments thereof are now described, purely by way of non-limiting example, with reference to the attached drawings, wherein:

FIG. 1 is a schematic cross-sectional view of an integrated electronic circuit;

FIG. 2 is a schematic top view of portions of the integrated electronic circuit illustrated in FIG. 1;

FIG. 3 is a schematic cross-sectional view of an alternate embodiment for the integrated electronic circuit of FIG. 1;

FIGS. 4-9 are schematic cross-sectional views of the electronic circuit illustrated in FIG. 1, during successive steps of a manufacturing process;

FIGS. 10-13 are schematic cross-sectional views of the electronic circuit illustrated in FIG. 3, during successive steps of a manufacturing process;

FIG. 14 is a schematic cross-sectional view of an alternate embodiment for the integrated electronic circuit;

FIG. 15 is a schematic top view of parts of an alternate embodiment for the integrated electronic circuit;

FIG. 16 is a schematic cross-sectional view of the embodiment shown in FIG. 15;

FIGS. 17 and 18 are schematic cross-sectional views of alternative embodiments for the integrated electronic circuit;

FIGS. 19-20 are schematic cross-sectional views of the electronic circuit illustrated in FIG. 18, during steps of a manufacturing process; and

FIG. 21 is a schematic cross-sectional view of an integrated electronic circuit.

### DETAILED DESCRIPTION

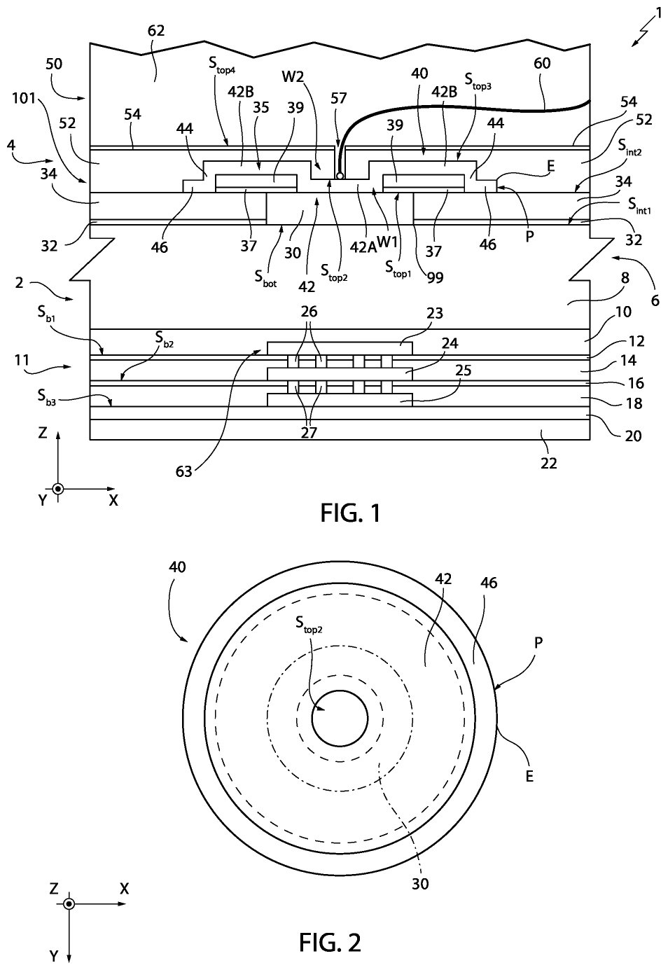

FIG. 1 shows an integrated electronic circuit 1, which comprises a main body 2 and a front structure 4.

Purely by way of example, the main body 2 comprises a dielectric body 6, which includes a first internal layer 8 and a second internal layer 10, which are formed, for example, of oxide.

The first internal layer 8 overlies, in direct contact, the second internal layer 10 and is delimited at the top by a first intermediate surface Sᵢₙₜ₁. The second dielectric layer 10 is delimited at the bottom by a first bottom surface S_{b1}.

The dielectric body 6 further comprises a stack 11 of bottom layers, arranged underneath the second internal layer 10. In particular, the stack 11 comprises a first bottom layer 12, a second bottom layer 14, a third bottom layer 16, a fourth bottom layer 18, and a fifth bottom layer 20, which are arranged in succession.

In greater detail, the first bottom layer 12 is formed, for instance, of oxide and is arranged underneath the second internal layer 10, with which it is in direct contact.

The second bottom layer 14 is formed, for instance, of dielectric material (e.g., oxide), is arranged between the first bottom layer 12 and the third bottom layer 16, with which it is in direct contact, and is delimited at the bottom by a second bottom surface S_{b2}.

The third bottom layer 16 is formed, for instance, of dielectric material (e.g., oxide) and is arranged between the second and fourth bottom layers 14, 18.

The fourth bottom layer 18 is formed, for instance, of dielectric material (e.g., oxide), is arranged between the third and fifth bottom layers 16, 20, and is delimited at the bottom by a third bottom surface S_{b3}.

The fifth bottom layer 20 is formed, for instance, of dielectric material (e.g., oxide) and overlies, in direct contact, a bottom region 22 of the main body 2, which is formed by a substrate of semiconductor material (e.g., silicon).

Purely by way of example, the integrated electronic circuit 1 further comprises a first bottom metallization 25, a second bottom metallization 24, and a third bottom metallization 23, which are formed, for example, of aluminum and belong to corresponding metallization levels of the integrated electronic circuit 1.

The third bottom metallization 23 extends in the second internal layer 10, starting from the first bottom surface S_{b1}, without traversing it entirely; the second bottom metallization 24 extends in the second bottom layer 14, starting from the second bottom surface S_{b2}, without traversing it entirely; and the first bottom metallization 25 extends in the fourth bottom layer 18, starting from the third bottom surface S_{b3}, without traversing it entirely. Once again without this implying any loss of generality, the third and second bottom metallizations 23, 24 are arranged in electrical contact with one another by a plurality of first conductive vias 26, which extend vertically through the first bottom layer 12 and part of the second bottom layer 14. Likewise, the second and first bottom metallizations 24, 25 are arranged in electrical contact with one another by a plurality of second conductive vias 27, which extend vertically through the third bottom layer 16 and part of the fourth bottom layer 18.

The integrated electronic circuit 1 further comprises a top conductive region 30, formed, for instance, of copper, which extends on the first intermediate surface Sinti, in direct contact with the underlying first internal layer 8. The top conductive region 30 belongs to the so-called top metallization level of the integrated electronic circuit 1; i.e., it belongs to the metallization level that is contacted to enable electrical coupling with the outside world. The top conductive region 30 thus belongs to a metallization level higher than the metallization levels to which the first, second, and third bottom metallizations 25, 24, 23, respectively, belong.

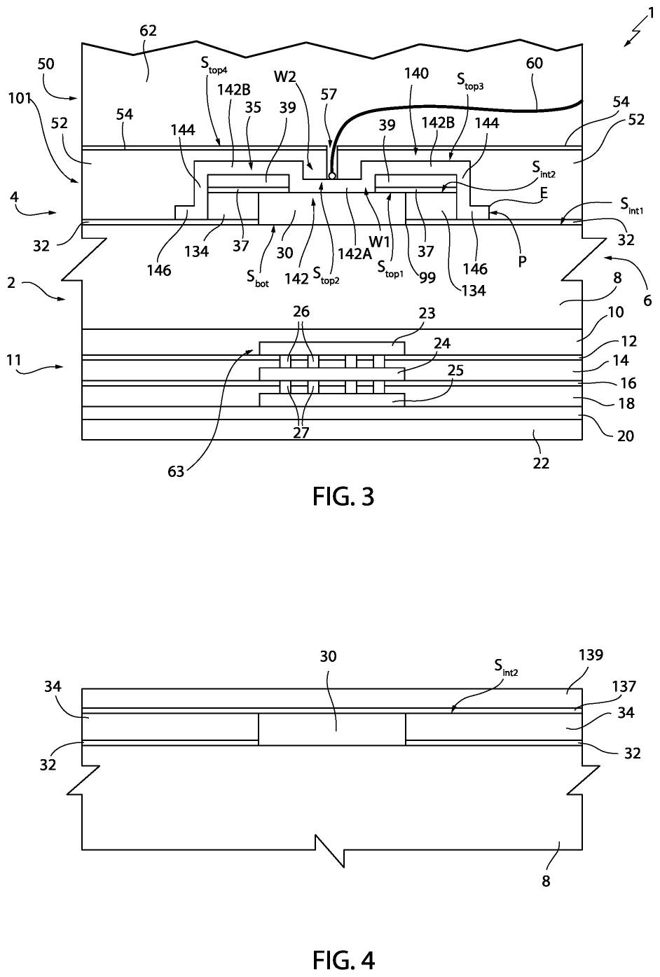

Without this implying any loss of generality, it is assumed that the top conductive region 30 has a cylindrical shape, as may be seen in FIG. 2; further, the top conductive region 30 is delimited at the top and at the bottom, respectively, by a first top surface Sₜₒₚ₁ and a base surface S_{bot}, the latter being delimited by a respective edge 99 having an approximately circular shape.

Furthermore, the dielectric body 6 comprises a first top layer 32 and a second top layer 34. The first top layer 32 is formed, for instance, of silicon nitride, extends on the first intermediate surface Sinti, in direct contact with the first internal layer 8, and is traversed by the top conductive region 30. In particular, the first top layer 32 laterally surrounds, in direct contact, a bottom portion of the top conductive region 30.

The second top layer 34 is formed, for instance, of TEOS oxide and overlies, in direct contact, the first top layer 32. In addition, the second top layer 34 is delimited at the top by a second intermediate surface Sᵢₙₜ₂, which is approximately planar, and is traversed by the top conductive region 30. In particular, the second top layer 34 laterally surrounds, in direct contact, a top portion of the top conductive region 30. Further, to a first approximation it is found that the first top surface Sₜₒₚ₁ is coplanar with the second intermediate surface Sᵢₙₜ₂; to a first approximation, the base surface S_{bot} is coplanar with the first intermediate surface Sᵢₙₜ₁.

The front structure 4 comprises a first passivation 35, which includes a respective first passivation region 37 and a respective second passivation region 39.

The first passivation region 37 is formed, for instance, of silicon nitride 37 and has the shape of an annulus, in top view. Furthermore, the first passivation region 37 extends, in direct contact, on a peripheral portion of the top conductive region 30, as well as on a portion of the second top layer 34 that laterally surrounds the aforementioned top portion of the top conductive region 30. In addition, the first passivation region 37 laterally delimits a bottom portion of a first opening W1, which gives out onto a central portion of the top conductive region 30. The first opening W1 has an approximately circular shape in top view.

The second passivation region 39 is formed, for instance, of TEOS oxide and has the shape of an annulus in top view. Further, the second passivation region 39 extends on the first passivation region 37, with which it is in direct contact. To a first approximation, in top view the second passivation region 39 has the same shape as the first passivation region 37. In addition, the second passivation region 39 laterally delimits a top portion of the first opening W1.

The front structure 4 further comprises a front conductive region 40, which is formed of a conductive material (e.g., aluminum) and in top view has a circular shape. As explained in what follows, the front conductive region 40 functions as a field plate.

In detail, the front conductive region 40 is formed by a respective internal portion 42, by a respective intermediate portion 44, and by a respective external portion 46, which form a single piece.

To a first approximation, the internal portion 42 of the front conductive region 40 has a circular shape, in top view, as illustrated in FIG. 2. Furthermore, a central part (designated by 42A) of the internal portion 42 of the front conductive region 40 extends within the first opening W1 so as to overlie, in direct contact, the aforementioned central portion of the top conductive region 30. A peripheral part (designated by 42B) of the internal portion 42 of the front conductive region 40 overlies, in direct contact, the second passivation region 39. In addition, the peripheral part 42B of the internal portion 42 of the front conductive region 40 laterally delimits a second opening W2, which gives out onto the central part 42A of the internal portion 42 of the front conductive region 40.

The intermediate portion 44 of the front conductive region 40 is interposed between the peripheral part 42B of the internal portion 42 of the front conductive region 40 and the external portion 46, and laterally coats, i.e., laterally surrounds in direct contact, the first and second passivation regions 37, 39.

The external portion 46 of the front conductive region 40 is arranged on the outside of the intermediate portion 44 and overlies, in direct contact, a portion of the second top layer 34. In other words, the external portion 46 functions as a terminal portion of the front conductive region 40. Further, the first opening W1 and the ensemble formed by the intermediate portion 44 and by the external portion 46 of the front conductive region 40 are arranged on opposite sides of the first passivation 35.

In practice, the front conductive region 40 has the shape of a cap, which overlies the top conductive region 30. Furthermore, the external portion 46 of the front conductive region 40 is laterally delimited by a wall P, which to a first approximation is vertical and is delimited at the top by an edge E, which to a first approximation has a circular shape.

In greater detail, assuming an orthogonal reference system XYZ with axes X and Y parallel to the first intermediate surface Stott and to the second intermediate surface Sᵢₙₜ₂, and denoting as third top surface Sₜₒₚ₃ the plane surface approximately parallel to the plane XY that delimits at the top the aforementioned peripheral part 42B of the internal portion 42 of the front conductive region 40, it is found that the edge E is located at a height, measured along Z, lower than the height at which the third top surface Sₜₒₚ₃ is located. In other words, the peripheral part 42B of the internal portion 42 of the front conductive region 40 and the external portion 46 are vertically staggered. In this way, to a first approximation, the external portion 46 and the peripheral part 42B of the internal portion 42 of the front conductive region 40 form the tread of a step, the rise of which is represented by the intermediate portion 44 of the front conductive region 40, said step descending outwards.

The front structure 4 further comprises a second passivation 50, which includes a first top passivation layer 52 and a second top passivation layer 54.

The first top passivation layer 52 is formed, for instance, of TEOS oxide and overlies, in direct contact, the front conductive region 40 and the portions of the second top layer 34 laterally staggered with respect to the front conductive region 40. The first top passivation layer 52 also extends within the second opening W2, filling it.

The second top passivation layer 54 is formed, for instance, of silicon nitride and overlies, in direct contact, the first top passivation layer 52.

A hole 57 extends vertically through a portion of the second top passivation layer 54 and an underlying portion of the first top passivation layer 52 so as to expose a portion of the central part 42A of the internal portion 42 of the front conductive region 40. In particular, the central part 42A of the internal portion 42 of the front conductive region 40 is delimited at the top by an approximately plane surface, referred to in what follows as the second top surface Sₜₒₚ₂; the hole 57 leaves a portion of the second top surface Sₜₒₚ₂ exposed.

The exposed portion of the second top surface Sₜₒₚ₂ electrically contacts (e.g., by bonding) a conductive wire 60 that extends in the hole 57, so as to provide, in a per se known manner, a so-called wire bonding and to enable electrical connection of the integrated electronic circuit 1 to the outside world, for example to bias the top conductive region 30.

The second passivation 50 further comprises an external passivation region 62, also known as “molding compound” and formed, for instance, of an organic plastic compound. The external passivation region 62 coats, in direct contact, the second top passivation layer 54 and fills the hole 57. The conductive wire 60 extends through the external passivation region 62, in a per se known manner.

In practice, the main body 2 and the front structure 4 form a die 101, which is delimited at the top by the second top passivation layer 54, which is delimited by a respective top surface (denoted as Sₜₒₚ₄), referred to as the front die surface Sₜₒₚ₄. The external passivation region 62 overlies the front die surface Sₜₒₚ₄. Furthermore, the top conductive region 30 forms, for example, a first plate of a capacitor 63, the second plate of which is formed, for example, by the third bottom metallization 23 and is vertically aligned to the first plate. In a per se known manner, and irrelevant for the purposes of the embodiment herein, the second and first bottom metallizations 24, 25 and the first and second conductive vias 26, 27 may form a conductive connection for biasing the second plate of the capacitor 63.

In use, the capacitor 63 may be subjected to a high voltage; the present applicant has in any case noted how the integrated electronic circuit 1 proves particularly resistant to the undesired phenomenon of dielectric breakdown. In fact, the present applicant has noted how, in use, the electric field, in addition to presenting a first peak in the proximity of the edge 99 of the base surface S_{bot} of the top conductive region 30, presents a second peak in the proximity of the edges of the wall P of the external portion 46 of the front conductive region 40, which, thanks to the lateral development of the front conductive region 40, is laterally arranged at a distance from the top conductive region 30; consequently, as the lateral development of the front conductive region 40 increases, the interaction between the first and second peaks of electric field decreases.

Further, thanks to the aforementioned step formed by the front conductive region 40, the wall P of the external portion 46 of the front conductive region 40 is overlaid by an area of dielectric material having a thickness greater than what is obtained for the peripheral part 42B of the internal portion 42 of the front conductive region 40; equivalently, the wall P of the external portion 46 of the front conductive region 40 is more distant from the front die surface Sₜₒₚ₄ with respect to the peripheral part 42B of the internal portion 42 of the front conductive region 40. Consequently, the second peak of electric field is sustained by a great thickness of overlying dielectric material, thus reducing the likelihood of a dielectric breakdown occurring in the proximity of the front die surface Sₜₒₚ₄.

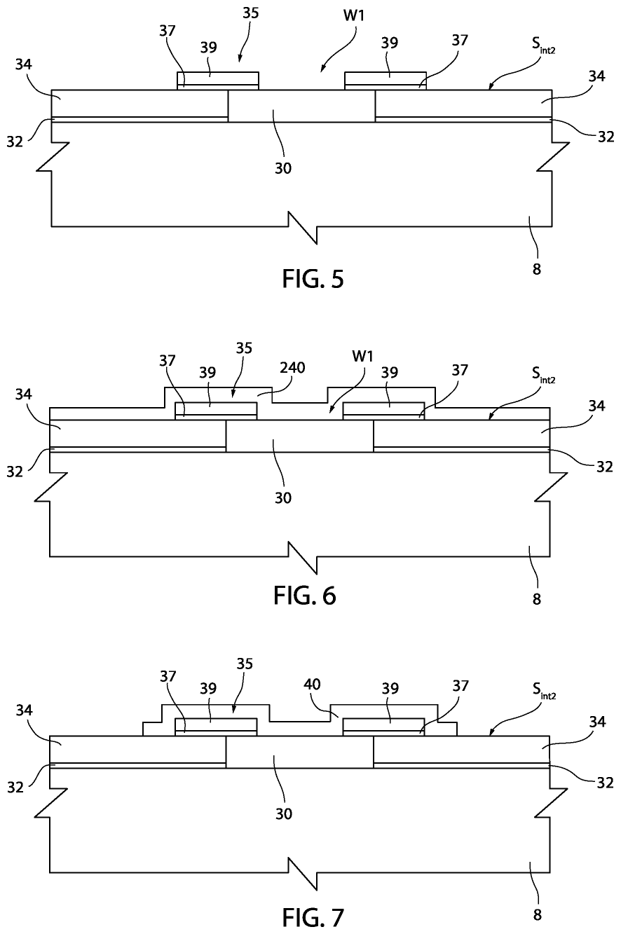

FIG. 3 shows a different embodiment, which is described in what follows with reference, for simplicity, to just the differences with respect to what is illustrated in FIG. 1. Elements already present in FIG. 1 are designated by the same references, except where otherwise specified.

In detail, the second top layer 34 is absent. A lateral region 134 instead is present, which is formed, for instance, of TEOS oxide, has the shape of an annulus, in top view, and laterally surrounds, in direct contact, the aforementioned top portion of the top conductive region 30; in addition, the lateral region 134 overlies, in direct contact, an underlying portion of the first top layer 32. The lateral region 134 is delimited at the top by the second intermediate surface Sᵢₙₜ₂.

The intermediate portion (here designated by 144) of the front conductive region (here designated by 140) laterally surrounds, in direct contact, the lateral region 134, in addition to the first and second passivation regions 37, 39; in other words, the intermediate portion 144 of the front conductive region 140 has a vertical extension greater than what is illustrated in FIG. 1. Furthermore, the external portion (here designated by 146) of the front conductive region 140 is once again arranged on the outside of the intermediate portion 144 and overlies, in direct contact, a portion of the first top layer 32 laterally staggered with respect to the lateral region 134. In FIG. 3, the internal portion of the front conductive region 140 is designated by 142. Further, the central part and the peripheral part of the internal portion 142 of the front conductive region 140 are designated, respectively, by 142A and 142B.

The first top passivation layer 52 overlies, in direct contact, the front conductive region 140 and portions of the first top layer 32 laterally staggered with respect to the front conductive region 140.

For practical purposes, the wall P of the front conductive region 40 is spaced at a further distance from the front die surface Sₜₒₚ₄ as compared to what is illustrated in FIG. 1. Consequently, the second peak of electric field is sustained by an even greater thickness of the overlying dielectric material, further reducing the likelihood of a dielectric breakdown occurring in the proximity of the front die surface Sₜₒₚ₄.

The present integrated electronic circuit 1 may be produced by the manufacturing process that is described in what follows, with reference to the embodiment illustrated in FIG. 1.

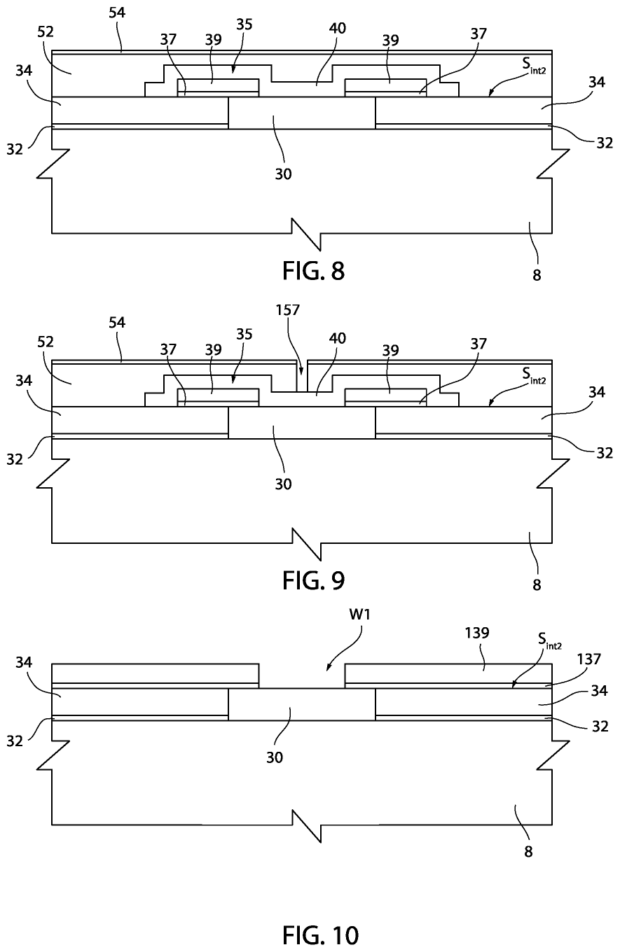

In detail, the ensuing description makes explicit reference to just the manufacturing of the part of integrated electronic circuit 1 that lies above the second intermediate surface Sᵢₙₜ₂. In fact, the main body 2, the top conductive region 30, and the first and second top layers 32, 34 are formed in a per se known manner. In this connection, in FIG. 4 and in the subsequent figures the part of the integrated electronic circuit 1 that lies underneath the first internal layer 8 is not illustrated.

This having been said, as shown in FIG. 4, a first layer 137 is formed on the second intermediate surface Sᵢₙₜ₂, referred to in what follows as the first process layer 137. A further layer 139 is formed on the first process layer 137, referred to as the second process layer 139. The first and second process layers 137, 139 are respectively formed, for example, of silicon nitride and TEOS oxide.

Next, as illustrated in FIG. 5, an etch is carried out, for example of a dry type, in order to selectively remove a portion of the second process layer 139 and an underlying portion of the first process layer 137 in order to form the first opening W1, exposing the central portion of the top conductive region 30, as well as in order to selectively remove further portions of the first and second process layers 137, 139 so that the remaining portions of the first and second process layers 137, 139 form, respectively, the first and second passivation regions 37, 39, and thus the first passivation 35. The aforesaid etch therefore enables exposure of portions of the second top layer 34 that are laterally staggered with respect to the first passivation 35.

Next, as illustrated in FIG. 6, a conductive layer 240, which is to form the front conductive region 40, is formed, for example, by deposition, on the first passivation 35, and in particular on the second passivation region 39, as well as within the first opening W1 and on the exposed portions of the second top layer 34.

Next, as illustrated in FIG. 7, a dry etch is carried out in order to selectively remove a portion of the conductive layer 240; the remaining portion of conductive layer 240 forms the front conductive region 40.

Then, as illustrated in FIG. 8, in a per se known manner the first and a second top passivation layers 52, 54 are formed in succession. Without this implying any loss of generality, FIG. 8 refers to the case where, prior to forming the second passivation layer 54, the first passivation layer 52 undergoes a planarization process.

Next, as illustrated in FIG. 9, portions of the first and second passivation layers 52, 54 are selectively removed so as to form the hole, here designated by 157.

Then, the manufacturing process proceeds in a per se known manner and consequently not described any further.

As regards the embodiment illustrated in FIG. 3, it may be manufactured by the process that is described hereinafter.

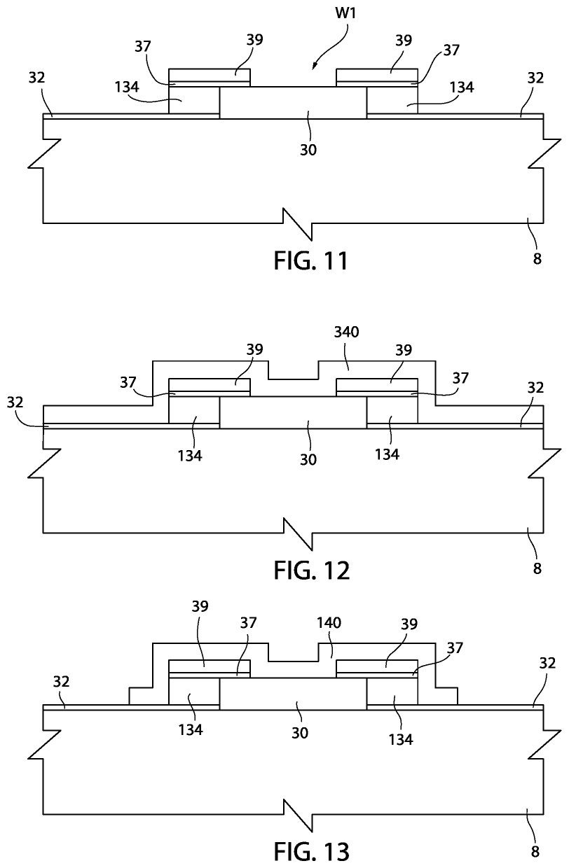

In detail, after having carried out the operations illustrated with reference to FIG. 4, as shown in FIG. 10 an etch, for example of a dry type, is carried out in order to selectively remove a portion of the second process layer 139 and an underlying portion of the first process layer 137 so as to form the first opening W1, exposing the central portion of the top conductive region 30.

Next, as illustrated in FIG. 11, a further etch is carried out, for example of a dry type, in order to selectively remove further portions of the first and second process layers 137, 139, as well as an underlying portion of the second top layer 34. The remaining portions of the first and second process layers 137, 139 form the first and second passivation regions 37, 39, respectively; the remaining portion of the second top layer 34 forms the lateral region 134. In addition, said etch enables exposure of a portion of the first top layer 32 that is laterally staggered with respect to the lateral region 134.

Then, as illustrated in FIG. 12, the conductive layer is formed, here designated by 340, which is to form the front conductive region 40. In particular, the conductive layer 340 is formed, for example, by deposition, on the second passivation region 39 and within the first opening W1. Furthermore, the conductive layer 340 coats laterally the first and second passivation regions 37, 39 and the lateral region 134 and coats the previously exposed portion of the first top layer 32.

Next, as illustrated in FIG. 13, a dry etch is carried out in order to selectively remove a portion of the conductive layer 340; the remaining portion of conductive layer 340 forms the front conductive region 140.

Then, the manufacturing process proceeds, as described with reference to the embodiment illustrated in FIG. 1.

The advantages of the present solution emerge clearly from the foregoing description. In particular, the front conductive region functions as field plate and enables reduction of the likelihood of a dielectric breakdown occurring in the proximity of the surface of the die.

Finally, it is clear that modifications and variations may be made to what has been described and illustrated, without thereby departing from the scope of the present invention, as defined in the annexed claims.

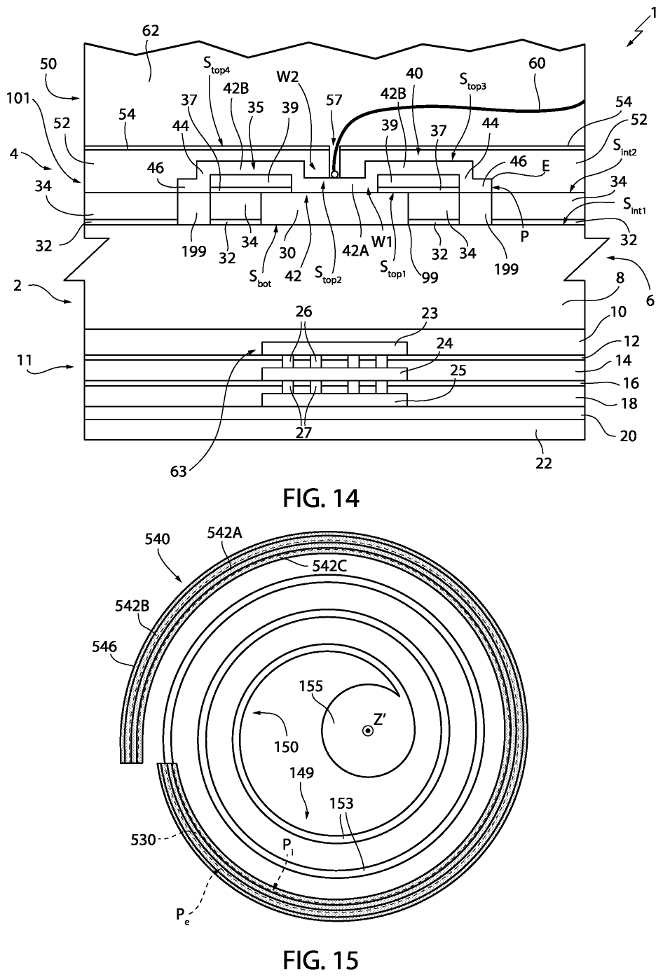

FIG. 14 shows a variant that includes, in addition to what is illustrated in FIG. 1, a further conductive region 199, referred to as the additional conductive region 199.

The additional conductive region 199 belongs, like the top conductive region 30, to the top metallization level of the integrated electronic circuit 1 and is formed of the same material as the top conductive region 30 (e.g., copper). Further, the additional conductive region 199 extends underneath the external portion 46 of the front conductive region 40, with which it is in direct contact, and traverses the first and second top layers 32, 34, until it contacts an underlying portion of the first internal layer 8.

The additional conductive region 199 has, for example, a circular symmetry and laterally surrounds, at a distance, the top conductive region 30. In top view, the additional conductive region 199 has, for example, the shape of an annulus.

For practical purposes, the additional conductive region 199 enables displacement of the aforementioned second peak of electric field as far as the height of the base surface S_{bot} of the top conductive region 30, with benefits similar to those described with reference to FIG. 3.

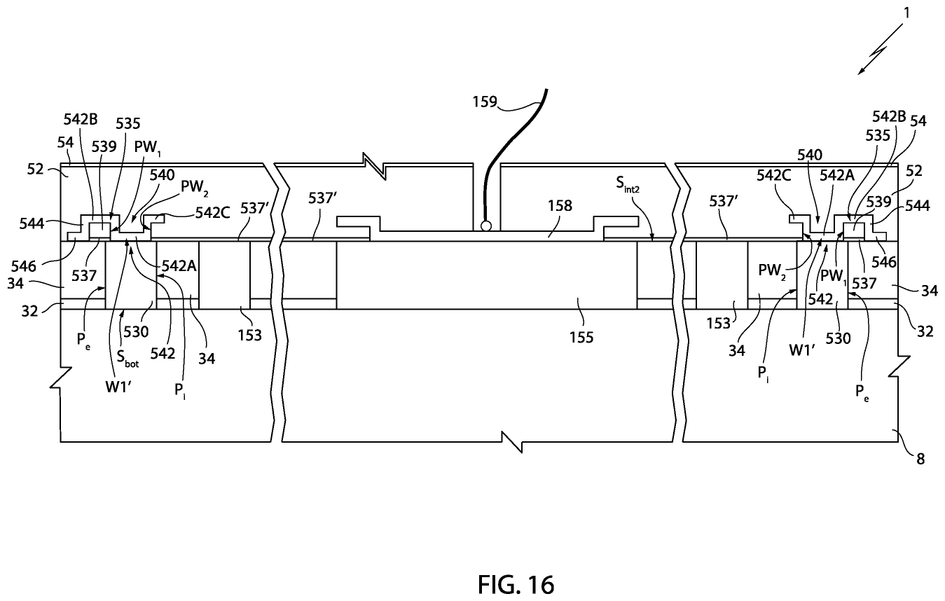

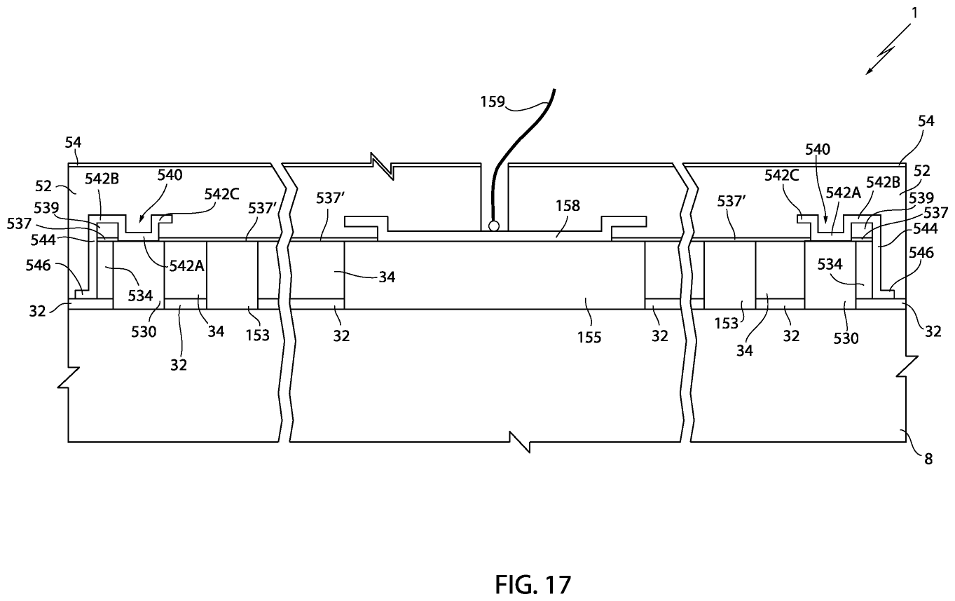

As illustrated in FIGS. 15 and 16, the present solution may apply also in the case where the integrated electronic circuit 1 integrates a component other than a capacitor.

Purely by way of example, in FIGS. 15 and 16 the integrated electronic circuit 1 forms an inductor 149, of a per se known type (shown here as a spiral). The ensuing description refers to the differences with respect to what is illustrated in FIG. 1.

In particular, the top conductive region, here designated by 530 forms a planar turn of a set of turns 150 that forms a spiral inductor. In particular, the turns of the set 150 are planar and coplanar with respect to one another and are formed in the highest metallization level of the integrated electronic circuit 1. In addition, the top conductive region 530 forms the outermost turn of the coil, and thus has an angular extension of 360°, measured with respect to a polar reference system with reference axis Z′ perpendicular to the plane where the turns lie. The set of turns 150 comprises, in addition to the outermost turn formed by the top conductive region 530, a plurality of inner turns, designated by 153; further, the set of turns 150 branches off from a terminal region 155, which is also formed in the highest metallization level of the integrated electronic circuit 1 and is overlaid by a contact pad 158 of a per se known type, coupled to a corresponding conductive terminal 159, to enable electrical coupling to the outside world.

The top conductive region 530 thus has a curvilinear development and is laterally delimited by an internal wall Pᵢ and by an external wall Pₑ, approximately parallel to the reference axis Z′.

The integrated electronic circuit 1 further comprises a layered region 537′, which is made of silicon nitride and extends on the set of turns 150, as well as on the parts of the second top layer 34 that are interposed between the turns of the set of turns 150.

The first opening, here designated by W1′, has the shape of a trench with curvilinear profile (in particular, a spiral profile, in top view), with approximately rectangular cross-section; said trench is delimited, on a first side facing the outside of the turn, by a first wall PW₁ and is further delimited, on a second side facing the inside of the turn, by a second wall PW₂. The first wall PW₁ is formed by the first passivation, here designated by 535; the second wall PW₂ is opposite to the first PW₁ and is formed by a portion of the layered region 537′ and by an overlying portion of the first top passivation layer 52.

In particular, the first passivation 535 includes the first passivation region, here designated by 537 and formed once again of silicon nitride, and the second passivation region, here designated by 539 and formed once again of TEOS oxide, which each have approximately the shape of a turn, are arranged on top of one another, and are the same in top view, as well as being laterally staggered outwards with respect to the top conductive region 530. The first passivation region 537 forms a monolithic layer with the layered region 537′.

The front conductive region, designated by 540, has the shape of a turn, in top view; thus it has a curvilinear shape, with angular extension equal, for example, to (approximately) 360°, as shown in FIG. 15, where for simplicity of illustration only the front conductive region 540, the set of turns 150, and the terminal region 155 are represented.

In particular, the front conductive region 540 once again comprises the internal portion (designated by 542), which includes the respective central part (designated by 542A), which extends within the first opening W1′, in direct contact with the top conductive region 530, and the respective peripheral part, designated by 542B, which extends on the first passivation 535, and in particular on the second passivation region 539, and also has the shape of a turn (in top view).

The front conductive region 540 further comprises the intermediate portion, here designated by 544, which laterally surrounds the first passivation 535, in direct contact with the first and second passivation regions 537, 539. In particular, the first opening W1′ and the intermediate portion 544 extend on opposite sides of the first passivation 535.

The external portion, here designated by 546, of the front conductive region 540 is arranged on the outside of the intermediate portion 544 and overlies, in direct contact, a portion of the second top layer 34. Further, the external portion 546 has the shape of a turn, in top view. The peripheral part 542B of the internal portion 542 of the front conductive region 540 and the external portion 546 are once again vertically staggered and form the treads of a step descending towards the outside of the first passivation 535.

The internal portion 542 of the front conductive region 542 further comprises an additional part 542C, referred to in what follows as the additional part 542C. In particular, the additional part 542C extends on the aforementioned portion of the first top passivation layer 52 that laterally delimits the first opening W1′ and forms the second wall PW₂, in a way substantially parallel to the second intermediate surface Sᵢₙₜ₂ and in the direction of the centre of the turn formed by the top conductive region 530. In top view, the additional part 542C has the shape of a turn.

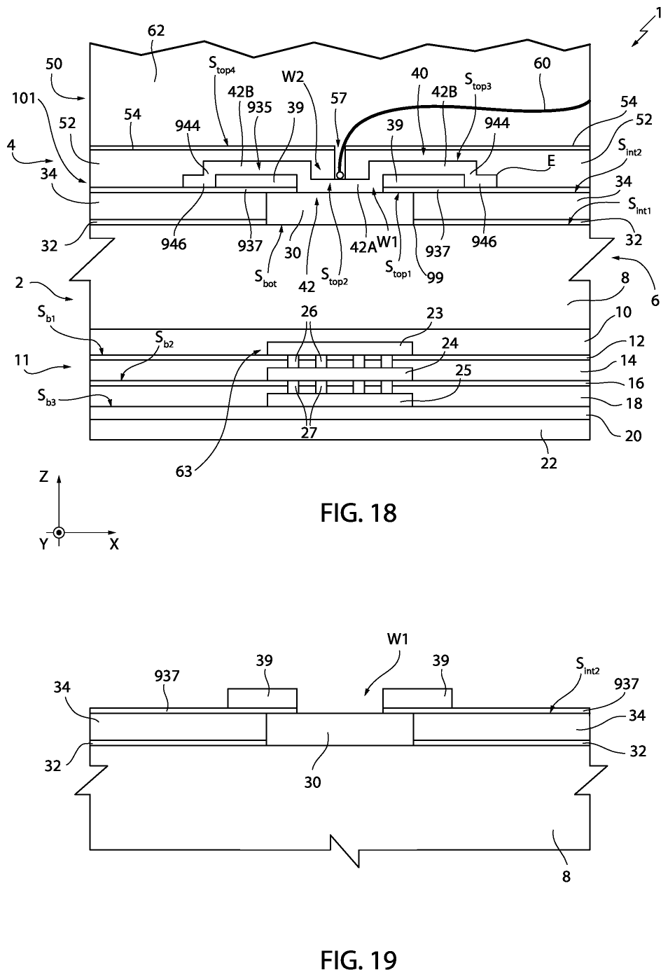

As illustrated in FIG. 17, likewise possible is an embodiment like the one illustrated in FIG. 16, but where the front conductive region 540 has a cross-sectional shape of the type illustrated in FIG. 3, i.e., such that the external portion 546 of the front conductive region 540 extends, in direct contact, on the first top layer 32. In this case, the second top layer 34 extends between the turns of the set of turns 150; further present is the lateral region, here designated by 534 and formed, for instance, of TEOS oxide. In particular, the lateral region 534 overlies, in direct contact, an underlying portion of the first top layer 32, has the shape of a turn, in top view, and laterally surrounds, in direct contact, the aforementioned top portion of the top conductive region 30; moreover, the lateral region 534 is delimited at the top by the second intermediate surface Sᵢₙₜ₂. The intermediate portion 544 of the front conductive region 540 laterally surrounds, in direct contact, the lateral region 534.

In addition, even though it is not illustrated, the inductor 149 comprises a further set of turns, which are, for example, the same as the set of turns 150, but formed in a lower metallization level.

It is likewise possible for the inductor 149 to comprise a further set of turns (not illustrated) coplanar with the set of turns 150, which is thus formed in the top metallization level and which forms a single conductive region with the set of turns 150; in this case, the top conductive region 530 may also form the outermost turn of the further set of turns, and the front conductive region 540 may extend also on said outermost turn of the further set of turns.

More in general, the field plate formed by the front conductive region may be used as contact region, to which an electrical connector of any type is soldered, irrespective of the type of electronic component that is implemented by the integrated electronic circuit. In particular, the aforementioned field plate finds advantageous use in the case of integrated electronic circuits that form high-voltage passive electronic components, for example defined during definition of the various metallization levels and during the so-called finishing. It is, however, possible to use the field plate formed by the front conductive region also in the case where the latter is not contacted directly by any electrical connector, as illustrated in the case of FIGS. 16 and 17.

Once again with reference to possible variants, the shape of the top conductive region may be different from what has been described; for example, it may have a polygonal shape, in top view. Likewise, also the shape of the front conductive region may be different from what has been described; also this may, for example, have a polygonal shape in top view.

As regards the top conductive region, the base surface S_{bot} may not be coplanar with the first intermediate surface Sᵢₙₜ₁; for example, the base surface S_{bot} may lie at a height lower than the height of the first intermediate surface Sᵢₙₜ₁; i.e., the top conductive region may extend partially within the first internal layer.

It is moreover possible for the first passivation region not to partially overlie the top conductive region. In other words, the peripheral portion of the top conductive region may be overlaid by the internal portion of the front conductive region instead of by the first passivation region.

Moreover possible are embodiments of the type illustrated in FIGS. 15-17, but where the profile of the turns is different. Furthermore, it is possible for the front conductive region 540 (and thus also the first opening W1′) to have an angular extension greater or less than 360′; for example, the front conductive region 540 may extend only over a part of the top conductive region 530.

The front conductive region may be conductive materials different from what has been described. Possibly, the top conductive region and the front conductive region may be also formed of a same material. In general, also the dielectric materials may be different from what has been described.

In the case of embodiments where the external portion of the front conductive region extends downwards until it contacts the first top layer 32, it is possible for the external portion of the front conductive region to penetrate at least in part through the first top layer 32, for example until it contacts the first internal layer 8.

Further possible are embodiments of the type illustrated in FIG. 18, which is now described with reference to the differences with respect to what is illustrated in FIG. 1.

In detail, whereas the second passivation region 39 has the same shape as that illustrated in FIG. 1, the first passivation region (here designated by 937) has a lateral extension greater than what is illustrated in FIG. 1 so that the external portion (here designated by 946) of the front conductive region 40 contacts at the bottom a portion of the first passivation region 937 laterally staggered with respect to the overlying second passivation region 39; the intermediate portion (here designated by 944) of the front conductive region 40 laterally coats, i.e., laterally surrounds in direct contact, just the second passivation region 39. The first passivation, formed by the first passivation region 937 and by the second passivation region 39, is designated by 935.

In practice, the external portion 946 of the front conductive region 40 rests on a portion of silicon nitride that forms the first passivation 935, with consequent benefits in terms of reduction of the likelihood of breakdown of the dielectric material in the direction of the second top layer 34; in this connection, silicon nitride is able to sustain high electric fields.

The above embodiment may be manufactured in the same way as described with reference to the embodiment illustrated in FIG. 1, but with the differences described in what follows.

In detail, after execution of the operations presented in FIG. 4, the operations illustrated in FIG. 10 are carried out so as to form the first opening W1, exposing the central portion of the top conductive region 30. The residual portion of the first process layer 137 forms the first passivation region 937.

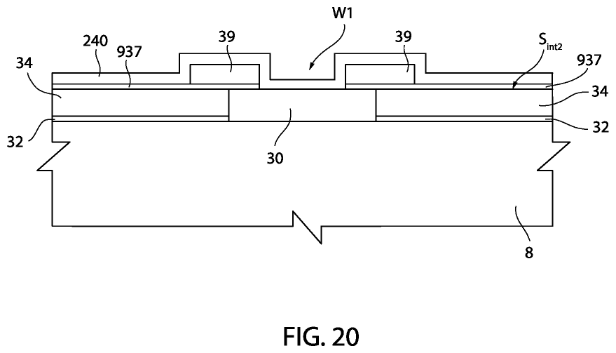

Next, as illustrated in FIG. 19, a further etch is carried out, for example of a dry type, in order to selectively remove further portions of the second process layer 139 so as to expose a portion of the first passivation region 937 laterally staggered with respect to the second passivation region 39, the latter being formed by the residual portion of the second process layer 139.

Then, the manufacturing process proceeds as described with reference to FIGS. 6-9, with the difference that, as illustrated in FIG. 20, the conductive layer 240 is formed, not only on the second passivation region 39 and within the first opening W1, but also on the exposed portion of the first passivation region 937. A subsequent selective removal (not illustrated) of portions of the conductive layer 240 leads to formation of the front conductive region 40.

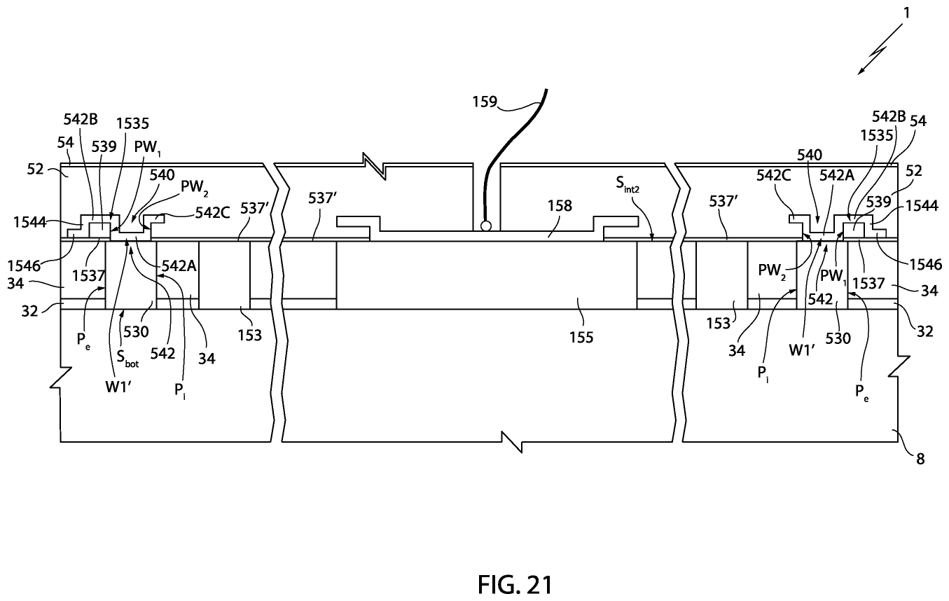

As illustrated in FIG. 21, also in the case of the inductor 149, the external portion (designated by 1546) of the front conductive region 540 may contact at the bottom the first passivation region (designated by 1537), instead of the second top layer 34, in a way similar to what is illustrated in FIG. 18. In this case, the first passivation region 1537 has a greater lateral extension than the second passivation region 539, with which it forms the first passivation (designated by 1535). Furthermore, the intermediate portion (designated by 1544) of the front conductive region 540 laterally surrounds just the second passivation region 539.

1. An integrated electronic circuit, comprising:
a dielectric body delimited by a front surface;
a top conductive region which extends within the dielectric body starting from the front surface of the dielectric body;
a first passivation structure including a bottom portion which extends on the front surface and a top portion which extends on the bottom portion, said first passivation structure laterally delimiting at least part of an opening where the top conductive region is located; and
a field plate of conductive material comprising:
an internal portion which is present within the opening in contact with the top conductive region and extends on the top portion of the first passivation structure; and
an external portion which extends laterally with respect to the top portion of the first passivation structure and has a bottom which contacts at least one of: the dielectric body and the bottom portion of the first passivation structure;
wherein said opening and said external portion are arranged on opposite sides of the top portion of the first passivation structure.

2. The integrated electronic circuit according to claim 1:
wherein the internal portion of the field plate comprises:
a central part located within the opening and in contact with the top conductive region; and
a peripheral part which extends on the top portion of the first passivation structure; and
wherein the external portion of the field plate comprises:
an intermediate part which laterally coats the bottom portion and the top portion of the first passivation structure; and
a terminal part which contacts the dielectric body and is staggered, along a direction perpendicular to said front surface, with respect to the peripheral part of the internal portion of the field plate; and
wherein the intermediate part of the external portion of the field plate is interposed between said terminal part and said peripheral part.

3. The integrated electronic circuit according to claim 2:
wherein the dielectric body comprises a top dielectric layer which is delimited by the front surface and is traversed by the top conductive region; and
wherein the bottom portion of the first passivation structure extends at least in part on the top dielectric layer; and
wherein the terminal part of the external portion of the field plate extends on the top dielectric layer.

4. The integrated electronic circuit according to claim 3:
wherein the first passivation structure laterally surrounds the opening; and
wherein the external portion of the field plate laterally surrounds at least the top portion of the first passivation structure.

5. The integrated electronic circuit according to claim 4, further comprising an additional conductive region, coplanar with the top conductive region, which is arranged underneath the terminal part of the external portion of the field plate, with which it is in direct contact, and which traverses the top dielectric layer surrounding at a distance the top conductive region.

6. The integrated electronic circuit according to claim 5, further comprising an electrical connector which is electrically and mechanically coupled to the central part of the internal portion of the field plate.

7. The integrated electronic circuit according to claim 6, wherein the top conductive region forms a plate of a capacitor.

8. The integrated electronic circuit according to claim 1:
wherein the internal portion of the field plate comprises:
a central part located within the opening and in contact with the top conductive region; and
a peripheral part which extends on the top portion of the first passivation structure; and
wherein the external portion of the field plate comprises:
an intermediate part which coats the top portion of the first passivation structure laterally; and
a terminal part which contacts the bottom portion of the first passivation structure and is staggered, along a direction perpendicular to said front surface, with respect to the peripheral part of the internal portion of the field plate; and
wherein the intermediate part of the external portion of the field plate is interposed between said terminal part and said peripheral part.

9. The integrated electronic circuit according to claim 8:
wherein the dielectric body comprises a top dielectric region delimited by the front surface and extends laterally, in direct contact, with respect to at least part of the top conductive region; and
wherein the bottom portion of the first passivation structure extends at least in part on the top dielectric region; and
wherein the external portion of the field plate extends laterally, in direct contact, with respect to the top dielectric region.

10. The integrated electronic circuit according to claim 9:
wherein the dielectric body comprises a base layer which extends underneath the top dielectric region and is made of a dielectric material different from that of the top dielectric region; and
wherein the terminal part of the external portion of the field plate contacts the base layer.

11. The integrated electronic circuit according to claim 9:
wherein the first passivation structure laterally surrounds the opening; and
wherein the external portion of the field plate laterally surrounds at least the top portion of the first passivation structure.

12. The integrated electronic circuit according to claim 11, wherein the top dielectric region laterally surrounds, in direct contact, the top conductive region; and wherein the external portion of the field plate laterally surrounds, in direct contact, the top dielectric region.

13. The integrated electronic circuit according to claim 12, further comprising an electrical connector, which is electrically and mechanically coupled to the central part of the internal portion of the field plate.

14. The integrated electronic circuit according to claim 13, wherein the top conductive region forms a plate of a capacitor.

15. The integrated electronic circuit according to claim 1:
wherein the top conductive region has the shape of a turn; and
wherein the opening has the shape of a trench shaped like a turn and is laterally delimited by an external wall, which faces the outside of the turn, and by an opposite internal wall, which faces the inside of the turn; and
wherein the first passivation structure extends on the outside of the turn-like shape of the opening and forms said external wall.

16. The electronic circuit according to claim 1, further comprising a second passivation structure which extends on the field plate.

17. The electronic circuit according to claim 1, further comprising a semiconductor substrate, and wherein the dielectric body overlies the semiconductor substrate.

18. The electronic circuit according to claim 1, wherein the field plate is formed of aluminum.

19. A process for manufacturing an integrated electronic circuit, comprising:
forming a dielectric body delimited by a front surface;
forming a top conductive region extending within the dielectric body starting from the front surface of the dielectric body;
forming a first passivation structure including a bottom portion which extends on the front surface and a top portion which extends on the bottom portion, wherein said first passivation structure laterally delimits at least part of an opening exposing the top conductive region; and
forming a field plate of conductive material which includes:
an internal portion within the opening in contact with the top conductive region and which extends on the top portion of the first passivation structure; and
an external portion which extends laterally with respect to the top portion of the first passivation structure and at the bottom contacts one of: the dielectric body or the bottom portion of the first passivation structure;
wherein said opening and said external portion are arranged on opposite sides of the top portion of the first passivation structure.

20. The manufacturing process according to claim 19, wherein forming the dielectric body comprises forming a top dielectric layer delimited by the front surface, said process further comprising:
forming a front dielectric structure on the front surface of the dielectric body;
selectively removing portions of the front dielectric structure so that the residual part of the front dielectric structure forms the first passivation structure and so as to expose a portion of the top dielectric layer laterally staggered with respect to the first passivation structure;
forming a conductive layer within the opening on the first passivation structure and on the exposed portion of the top dielectric layer; and
selectively removing a portion of the conductive layer so that the residual portion of the conductive layer forms the field plate, the external portion of the field plate extending on the top dielectric layer.

21. The manufacturing process according to claim 19, wherein forming the dielectric body comprises forming a top dielectric layer delimited by the front surface and traversed by the top conductive region, said process further comprising:
forming a front dielectric structure on the front surface of the dielectric body;
carrying out a first selective removal of a first portion of the front dielectric structure so as to form the opening; and
carrying out a second selective removal of a second portion of the front dielectric structure and of an underlying portion of the top dielectric layer so that the residual portion of the front dielectric structure forms the first passivation structure and the residual portion of the top dielectric layer forms a top dielectric region that extends laterally, in direct contact, with respect to at least part of the top conductive region; and wherein said second selective removal comprises exposing a portion of the dielectric body laterally staggered with respect to the top dielectric region.

22. The manufacturing process according to claim 21, wherein forming a field plate comprises:
forming a conductive layer that extends within the opening, on the first passivation structure and on the exposed portion of the dielectric body and laterally coats the top dielectric region; and
selectively removing a portion of the conductive layer so that the residual portion of the conductive layer forms the field plate, the external portion of the field plate extending laterally, in direct contact, with respect to the top dielectric region.

23. The manufacturing process according to claim 21, wherein forming the dielectric body comprises forming a base layer underneath the top dielectric layer; and wherein carrying out the second selective removal comprises exposing a portion of the base layer laterally staggered with respect to the top dielectric region; and wherein forming the conductive layer comprises forming the conductive layer so that it extends on the exposed portion of the base layer; and wherein the external portion of the field plate contacts the base layer.

24. The manufacturing process according to claim 19, wherein forming the first passivation structure comprises:
forming a first process dielectric layer on the front surface of the dielectric body;
forming a second process dielectric layer on the first process dielectric layer, said second process dielectric layer being made of a dielectric material different from that of the first process dielectric layer; and
then carrying out a selective removal of a first portion of the second process dielectric layer and of an underlying portion of the first process dielectric layer so as to form the opening, the residual portion of the first process dielectric layer forming said bottom portion of the first passivation structure; and
then carrying out a selective removal of a second portion of the second process dielectric layer so as to expose a part of the bottom portion of the first passivation structure, the residual portion of the second process layer forming the top portion of the first passivation structure.

25. The manufacturing process according to claim 24, wherein forming a field plate comprises:
forming a conductive layer that extends within the opening, on the top portion of the first passivation structure and on the exposed part of the bottom portion of the first passivation structure; and
then selectively removing a portion of the conductive layer so that the residual portion of the conductive layer forms the field plate.

26. The manufacturing process according to claim 19, further comprising forming a second passivation structure on the field plate.
